(19) United States
(12) Patent Application Publication
(10) Pub. No.: US 2026/0314148 A1
(43) Pub. Date: Oct. 8, 2026

(54) DISPLAY PIXEL AND METHOD OF PRODUCING COLOR FOR A DISPLAY UTILIZING A METAL-ORGANIC CHALCOGENIDE CRYSTAL

(71) Applicant: The Board of Trustees of the University of Illinois, Urbana, IL (US)

(72) Inventors: Zichao Ye, San Jose, CA (US); Jie Zhao, Hillsboro, OR (US); Leslie H. Allen, Champaign, IL (US)

(21) Appl. No.: 19/637,342

(22) Filed: Apr. 2, 2026

Related U.S. Application Data
(60) Provisional application No. 63/785,293, filed on Apr. 8, 2025.

(51) Int. Cl. H10H 29/855; H10H 29/01

(52) U.S. Cl. CPC H10H 29/855; H10H 29/0363

(57) ABSTRACT

A method of producing color for a display includes emitting light from a light source in optical communication with an optical system that includes a first linear polarizer; a second linear polarizer cross-polarized with respect to the first linear polarizer; and a birefringent flake comprising a metal-organic chalcogenide disposed between the first and second linear polarizers and oriented along a plane parallel to the polarizers. The birefringent flake is rotated within the plane, and a color of the light transmitted through the optical system changes as the birefringent flake is rotated.

### RELATED APPLICATION

The present patent document claims the benefit of priority under 35 U.S.C. 119 (e) to U.S. Provisional Patent Application No. 63/785,293, which was filed on Apr. 8, 2025, and is hereby incorporated by reference in its entirety.

### STATEMENT OF FEDERALLY FUNDED RESEARCH OR DEVELOPMENT

This invention was made with government support under 1409953 awarded by the National Science Foundation and 1809573 awarded by the National Science Foundation. The government has certain rights in the invention.

### TECHNICAL FIELD

The present disclosure relates generally to electronic displays and more particularly to a method of producing color for a display that utilizes metal-organic chalcogenide single crystals.

### BACKGROUND

A display pixel has a capability to switch/generate colors under controllable conditions. Traditional liquid crystal displays (LCDs) employ transmissive red-green-blue (RGB) color filter materials for color generation, and traditional organic light emitting diode (OLED) displays employ RGB pixel materials with corresponding emissive spectra for color generation. Both displays utilize separate red, green and blue sub-pixels to display different colors. By varying the intensity of the sub-pixels, a wide range of colors can be created. Both prevalent display architectures require a design with separate RGB pixels. It would be beneficial to develop a different mechanism for color generation.

### SUMMARY

A method of producing color for a display, a pixel for a display, and a method of making birefringent flakes for optical applications are described in this disclosure.

The method of producing color for a display comprises emitting light from a light source in optical communication with an optical system, which includes a first linear polarizer, a second linear polarizer cross-polarized with respect to the first linear polarizer, and a birefringent flake comprising a metal-organic chalcogenide positioned between the first and second linear polarizers, where the birefringent flake is oriented along a plane parallel to the first and second linear polarizers. The birefringent flake is rotated within the plane, and a color of the light transmitted through the optical system changes as the birefringent flake is rotated.

The pixel for a display comprises an optical system that includes a first linear polarizer, a second linear polarizer cross-polarized with respect to the first linear polarizer, and a birefringent flake comprising a metal-organic chalcogenide positioned between the first and second linear polarizer, where the birefringent flake is oriented along a plane parallel to the first and second linear polarizers and is rotatable within the plane. When light from a light source passes through the optical system, the light transmitted has a color depending on a rotation angle of the birefringent flake.

The method of making birefringent flakes includes: dissolving a metal-organic chalcogenide in a solvent to form a mixture, wherein the metal-organic chalcogenide has a concentration in a range from 6 μmol/ml to 15 μmol/ml in the mixture; heating the mixture to ensure complete dissolution of the metal-organic chalcogenide; cooling the mixture at a rate in a range from 20° C./h to 30° C./h, whereby recrystallization of the metal-organic chalcogenide occurs; and obtaining single-crystalline birefringent flakes comprising the metal-organic chalcogenide and having a thickness of at least about 1 micron.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The embodiments may be better understood with reference to the following drawing(s) and description. The components in the figures are not necessarily to scale. Moreover, in the figures, like-referenced numerals designate corresponding parts throughout the different views.

FIG. 1 is a schematic of an optical system for a display pixel based on a metal-organic chalcogenide flake.

FIG. 2 shows dark-field optical images of AgSC₆H₁₃ (AgSC6) and AgSC₇H₁₅ (AgSC7) single crystal flakes and (inset) nano-beam electron diffraction (NBD) patterns at two different locations on the flake to verify the single crystalline nature of AgSC7; the zoomed-in image reveals that the long cleaved edges of the flake are oriented along the —(Ag—S)_{∞}-direction, confirmed by NBD.

FIG. 3 shows an assembly of optical images of large-size single crystal flakes of AgSCₙH₂ₙ₊₁ (AgSCn), where n=4, 5, 6, 8.

FIG. 4 shows X-ray diffraction (XRD) data (rocking curve) obtained from a AgSC7 flake that verifies its single crystalline nature.

FIGS. 5A and 5B show an exemplary design for a display pixel where different colors are obtained by rotation of a single metal-organic chalcogenide flake.

FIGS. 6A-6F show lattice of AgSCn (n=3-8) determined by a hybrid method combining synchrotron XRD and NBD along with density functional theory (DFT) relaxation showing the Ag—S network and attached alkyl chains, where Ag atoms are gray, S atoms are yellow, and alkyl chains are brown.

FIGS. 7A-7F show 2D structures of the Ag—S network of AgSCn (n=3-8) viewed from the b-axis where Ag atoms are gray, S atoms are yellow, and alkyl chains are brown.

FIG. 8 shows a series of polarization-resolved optical microscopy (PROM) images that present a progressive color change as a function of rotation of a AgSC7 flake.

FIG. 9 shows an assembly of multiple AgSC7 single crystals with blue and orange colors, as a result of different crystal rotations.

FIG. 10 shows transmission-mode UV-vis spectra measured on AgSCn flakes (n=4-8) at different sample rotation angles) (−45~45°).

FIG. 11 provides a visualization of color change of AgSC7 flakes upon rotation angle from −45~45° in the International Commission on Illumination (CIE) 1931 chromaticity diagram, where each black box refers to the corresponding color of a certain spectrum shown in FIG. 10.

FIGS. 12A-12E show polar plots revealing a strong angular-dependent transmittance of AgSCn flakes (n=4-8) at 400, 450, 500, 600, and 700 nm wavelengths using the optical set-up of FIG. 1.

FIG. 13 provides schematics that trace light rays through the first linear polarizer, the metal-organic chalcogenide flake (on a transparent substrate), and the second linear polarizer.

FIG. 14 provides a plot showing birefringence value (Δn) as a function of wavelength for AgSCn (n=4-8); the inset shows the odd/even effect of maximum Δn (across wavelength of 330~700 nm) as a function of chain length.

FIG. 15 provides a plot showing dielectric frame orientation (a) as a function of wavelength for AgSCn (n=4-8); the inset shows the range of α (Δα=α(330 nm)−α(700 nm)) as a function of chain length.

FIG. 16 is an illustration that overlays the dielectric frame of AgSC7 at 400, 450, 500, 600 and 700 nm onto its in-plane lattice structure.

### DETAILED DESCRIPTION

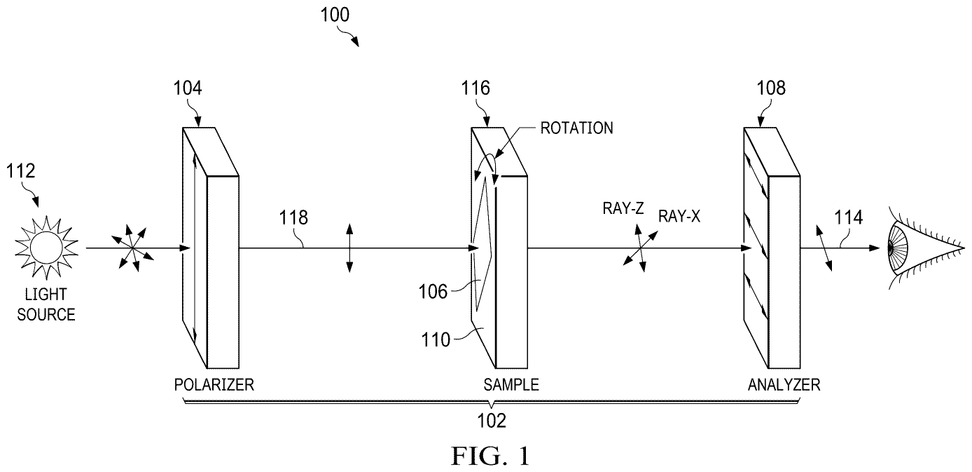

Described in this disclosure is a display pixel and a method of producing color for a display that exploit the in-plane birefringence achievable in thick, single-crystalline metal-organic chalcogenide flakes. Also described in this disclosure is a method of making metal-organic chalcogenide flakes that are 100 times larger and 10 times thicker than previous flakes and thus suitable for application as birefringent color filters. Strong in-plane birefringence has been demonstrated for the first time in a metal-organic chalcogenide flake due to the increased thickness. By coupling a single-crystalline metal-organic chalcogenide flake with a cross-polarized illumination setup as described below in reference to FIG. 1, it is possible to obtain a sharp color change from the crystal, e.g., in the example of a silver alkanethiolate, from orange to blue, and to purple within about 12 degrees of crystal rotation. The metal-organic chalcogenide crystal can sensitively change its color via crystal rotation which covers the entire visible light spectrum (400-700 nm). This behavior may enable a new color-switching mechanism for display pixel design.

Metal-organic chalcogenides, such as silver alkanethiolate (AgSCₙH₂ₙ₊₁ or AgSCn, where n represents carbon chain length) have a metal-chalcogen network with organic ligands; the metal of the metal-organic chalcogenide may comprise Ag, Au, and/or Cu, the chalcogen may comprise sulfur(S), selenium (Se) and/or tellurium (Te), and the organic ligands may be alkyl chains (CₙH₂ₙ₊₁), where n is typically in a range from 3 to 15, or from 3 to 8. The metal-organic chalcogenide may have a layered structure and may be referred to as a two-dimensional (2D) material. The single-crystalline birefringent flakes comprising the metal-organic chalcogenide that are described in this disclosure may alternatively be referred to as birefringent 2D crystals.

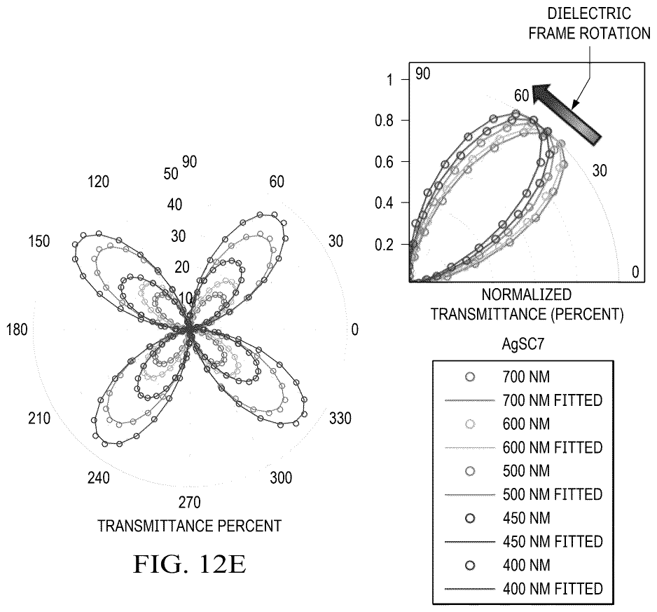

Referring to FIG. 1, a pixel 100 for a display includes an optical system 102 comprising a first linear polarizer 104 and a second linear polarizer 108 cross-polarized with respect to the first linear polarizer 104. In other words, the first linear polarizer 104 is positioned such that its transmitting axis is perpendicular to the transmitting axis of the second linear polarizer 108. A birefringent flake 106 comprising a metal-organic chalcogenide is positioned between the first and second linear polarizers 104, 108 and is oriented along a plane 110 parallel to the polarizers 104,108, as can be appreciated from the schematic of FIG. 1. The plane 110 may be an imaginary plane or a supporting surface of an optically transparent substrate 116, which is discussed further below. With this orientation of the birefringent flake 106, a thickness direction of the birefringent flake 106 is normal to or perpendicular to the first and second linear polarizers 104, 108. The thickness direction of the birefringent flake 106 may also or alternatively coincide with a crystallographic axis of the flake 106, e.g., the b-axis of a monoclinic crystal structure. The birefringent flake 106 has an anisotropic in-plane structure with a refractive index that varies with direction, such that an incident light ray is split into two rays when passing through the thickness of the flake 106. This is illustrated in more detail in FIG. 13, which is discussed below.

Referring again to the display pixel 100 of FIG. 1, the birefringent flake 106 is configured to undergo in-plane rotation. In other words, the birefringent flake is configured to be manually or automatically rotated within the plane 110. The in-plane rotation of the birefringent flake 106 may take place about the axis 118 shown in FIG. 1, which is normal to the linear polarizers 104, 108. The axis of rotation of the flake 106 may also correspond to a crystallographic axis of the single-crystalline flake 106, e.g., the crystallographic b-axis in the example of AgSCn, which has a monoclinic crystal structure. When light from a light source 112 passes through the optical system 102, the light transmitted 114 has a color depending on a rotation angle of the birefringent flake 106. In other words, the color of the transmitted light 114 can be changed by rotating the birefringent flake 106. The flake 106 may be rotated clockwise or counter-clockwise from a position defined as 0° by any amount in a range from greater or less than 0° to +/−45° to achieve any desired color in the visible spectrum (400-700 nm). If 0° is assigned to the rotation angle at which the flake is darkest, the color of the flake may be red-shifted when the rotation is clockwise, and blue-shifted when the rotation is counter-clockwise. Both shifts may converge to a same chroma when the crystal appears brightest, which may be at rotation angles of about ±45°, as discussed below.

It is noted that the color of the transmitted light is sharpest, that is, has the highest color purity and contrast, when the transmitting axes of the first linear and second polarizers 104,108 are oriented exactly perpendicular, that is, exactly 90° from each other. Deviations from 90° may lead to higher whiteness and less sharpness/contrast. However, it is still possible to obtain distinct colors if the transmitting axes of the linear polarizers 104, 108 are not exactly perpendicular but are substantially perpendicular, that is, have a relative orientation in a range from 80°-100° (±10° from) 90°. Accordingly, the term “perpendicular to” or “cross-polarized” as used anywhere in this disclosure may be understood to refer to a relative angular orientation of exactly 90° or within ±10° from 90°.

Similarly, the color of the transmitted light is sharpest, that is, has the highest color purity and contrast, when the birefringent flake 106 is oriented along a plane 110 exactly parallel to the polarizers 104,108, or, stated differently, when the birefringent flake 106 has a thickness direction oriented exactly perpendicular to the first and second linear polarizers 104, 108. Deviations from this orientation may lead to higher whiteness and less sharpness/contrast. However, it is still possible to obtain distinct colors if the birefringent flake 106 is oriented along a plane 110 that is not exactly parallel to the polarizers 104,108 but is substantially parallel to the polarizers 104,108, that is, has an orientation within ±10° from exactly parallel) (0°). Accordingly, the term “parallel to” as used anywhere in this disclosure may be understood to refer to a relative angular orientation of exactly 0° or within ±10° from 0°.

A suitable light source 112 emits white light and may comprise a light emitting diode (LED) or another source of unpolarized white light. The optical system 102 may further include an optically transparent, non-polarizing substrate 116 supporting the birefringent flake 106. With this configuration, the substrate 116 may be rotated in order to rotate the birefringent flake 106. The optically transparent, non-polarizing substrate 116 is preferably glass, as some optically transparent polymers may act as polarizers. The rotation may be driven by a motor, such as a micromotor, that is directly connected or indirectly connected (e.g., via one or more other components) to the substrate 116 or flake 106 and is electrically connected to a controller.

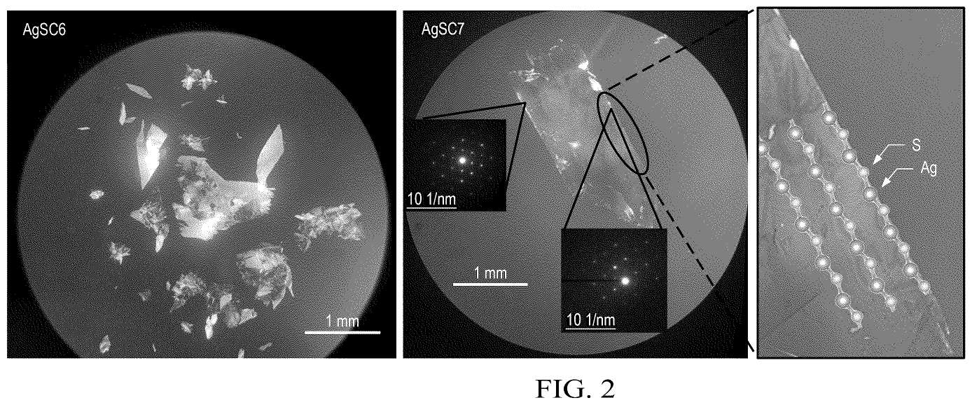

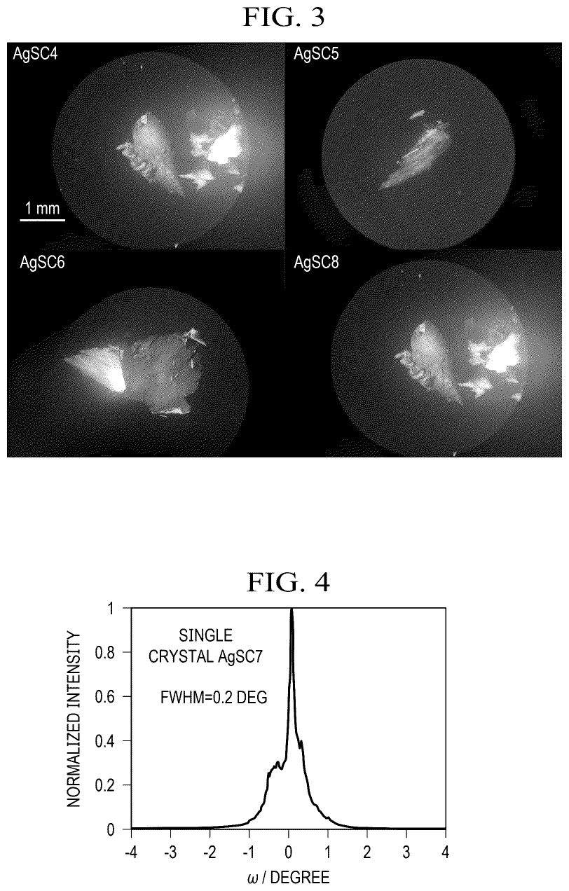

To achieve the desired in-plane birefringence, the flake preferably has a thickness of at least 1 micron, at least 2 microns, or at least 3 microns, and/or as large as 8 microns. An intensity of the light transmitted through the optical system depends on the thickness of the birefringent flake, where thicker flakes produce brighter light. If the flake is too thin (e.g., less than 1 micron), then the brightness of the pixel color may be too low for practical use. This is because, at low thickness, the transmitted intensity is approximately proportional to the square of the flake thickness. On the other hand, if the flake is too thick (e.g., larger than 8 microns), the relationship between intensity and thickness may be non-linear and the increased thickness may lead to a decrease of intensity/brightness. In addition, more light may be absorbed by the thicker flake and thus the transmitted intensity may be further reduced. The lateral size of the flakes may be on the order of millimeters (e.g., up to 3 mm) with lateral sizes in the range from 10 microns to 3 mm being readily achievable. A recrystallization method with a controlled cooling process described below allows for the larger size of the AgSCn flakes, which have well-defined edges and surfaces, as can be seen in the optical images of FIGS. 2 and 3, which show AgSCn flakes with n=4-8. For use in a display device, a single flake with a large lateral size may be cut into smaller flakes of a uniform thickness to form multiple pixels.

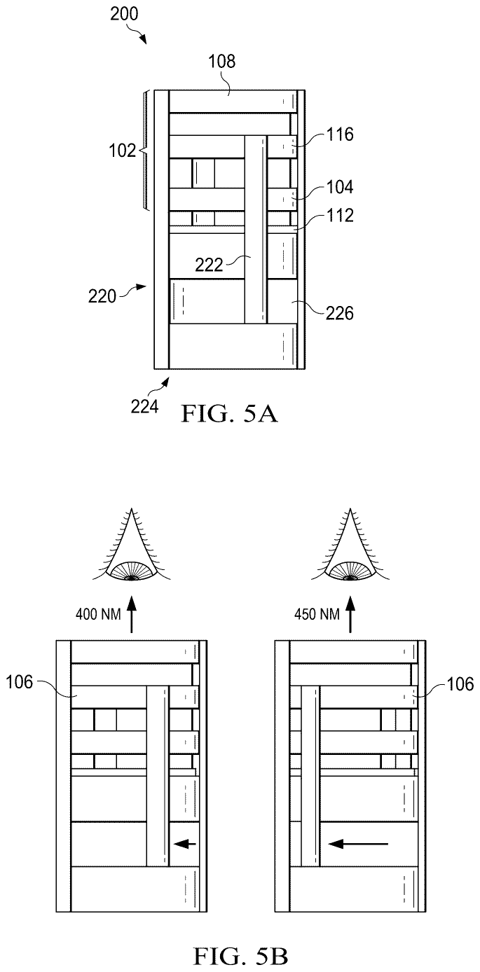

The birefringent flakes 106 are single-crystalline and may be semiconducting. Their single-crystalline nature is verifiable by electron and/or x-ray diffraction measurements. For example, the former reveals identical diffraction patterns at two different locations on the same AgSC7 flake (FIG. 2 inset), and the latter presents a sharp rocking curve (FIG. 4) with a narrow full-width-half-maximum (FWHM) of ~0.2°, suggesting an extremely low degree of mosaicity (misorientation of crystals) of the single crystal flake.

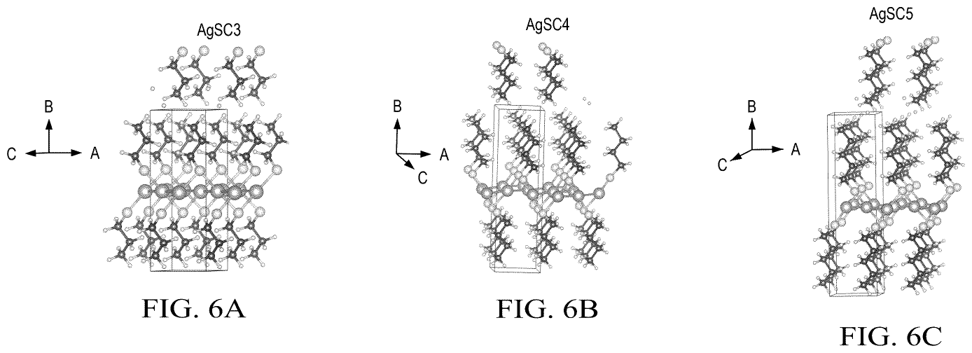

FIGS. 5A-5B show an example of a pixel design 200 for the optical system 102, where the optically transparent, non-polarizing substrate 116 used for supporting the birefringent flake 106 has a circular shape and is rotatable within a cylindrical framework 220 that holds the first and second linear polarizers 104,108 stationary. The rotation occurs within the plane of the flake 106/substrate 116 about a longitudinal axis of the cylindrical framework 220. As illustrated in FIG. 5B, the optically transparent substrate 116 may be configured to rotate along with a rotatable portion 226 of the cylindrical framework 220 that is driven by an internal motor 224. In one example, the optically transparent substrate 116 may be connected to the rotatable portion 226 by one or more longitudinal rods 222, as shown. The color generated by a birefringent 2D crystal supported on the optically transparent substrate 116 can be varied by the amount of rotation as described above. For example, a birefringent flake comprising a metal-organic chalcogenide that appears purple at a first angle may appear blue (or another hue) after rotation to a second angle, as illustrated in FIG. 5B.

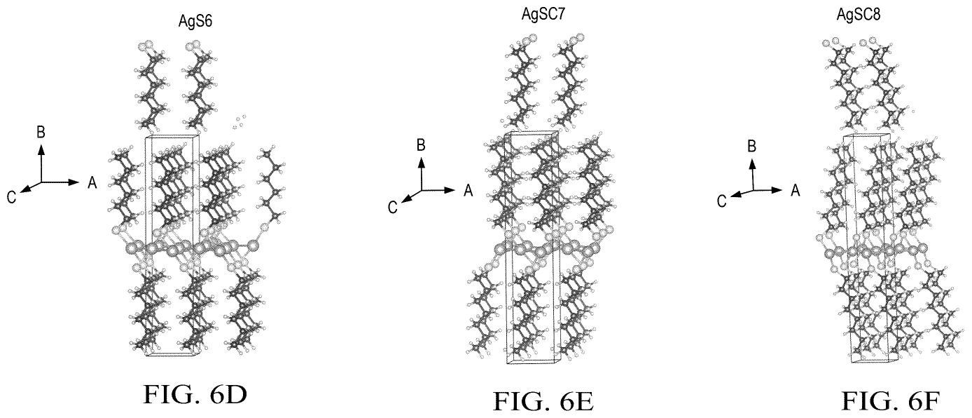

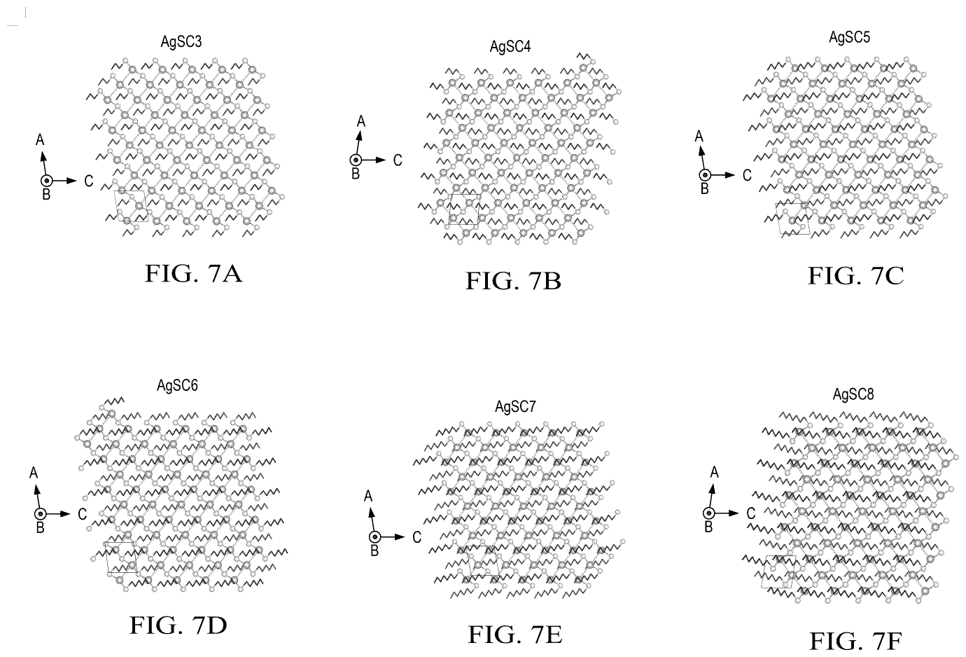

It has been discovered in experiments described below that the amount of crystal rotation required to obtain a given color may depend on n, the carbon chain length of the metal-organic chalcogenide. The lattices of AgSCn for n=3-8 as determined by a hybrid method combining diffraction experiments and modeling are shown in 3D renderings in FIGS. 6A-6F. The lattice structures and unit cells viewed from the b-axis (normal to lamellar stacking direction), which illustrates the Ag—S network and projection of alkyl chains, are shown in FIGS. 7A-7F. Two distinct orientations of —(Ag—S)_{∞}— and —(Ag—Ag)_{∞}— with different bonding types have been identified for the anisotropic Ag—S network, which fundamentally induces a maximum ~8× disparity of in-plane semiconductivity and an evident birefringence across the entire visible light regime with a wavelength-dependent rotation of dielectric frame (as opposed to crystallographic axes). Although various AgSCn (n=3-8) crystals share a common Ag—S framework, the anchoring of alkyl chains of different lengths and parity deforms the inorganic backbone progressively, which in turn alters the configurations of ligands, as discussed further below. This mechanism may offer a new knob for modulating the characteristics of metal-organic chalcogenides. The work described in this disclosure is believed to be the first time dielectric frame rotation with an odd/even effect is observed in birefringent 2D layered crystals. The in-plane anisotropy of the Ag—S network and the out-of-plane odd/even modulation from the alkyl chains suggest that AgSCn single crystals may be well-suited for devices that demand optical/electrical anisotropy and color filtering with tunable/configurable characteristics.

An array of the pixels may be used to form a display. Each pixel may be independently controllable and may include a micromotor configured to rotate the respective birefringent 2D crystal to provide a desired color output. Accordingly, an image may be formed from the array of pixels. The image may be changed as rapidly as the rotation may occur. The display may include thousands or millions of the pixels.

In addition to a pixel for display, a method of producing color for a display is also described. In contrast to conventional displays which require multiple RGB sub-pixels to produce color, the display and method described in this disclosure can generate any desired color over the visible spectrum from a single pixel via crystal rotation. The method includes emitting light from a light source, where the light source is in optical communication with an optical system comprising: a first linear polarizer; a second linear polarizer cross-polarized with respect to the first linear polarizer; a birefringent flake comprising a metal-organic chalcogenide between the first and second linear polarizers, the birefringent flake being oriented along a plane substantially parallel to the first and second linear polarizers. The birefringent flake undergoes in-plane rotation to change the color of light transmitted through the optical system. The birefringent flake employed for the method may have any of the characteristics or properties described above or elsewhere in this disclosure.

Also described is a recrystallization method that can produce metal-organic chalcogenide crystals of a suitable size to obtain in-plane birefringence. The method includes dissolving a metal-organic chalcogenide (e.g., in the form of precipitates, particles, a powder, or the like) in a solvent to form a mixture, where the metal-organic chalcogenide has a concentration in a range from 6 μmol/ml to 15 μmol/ml in the mixture; heating the mixture to a temperature to ensure complete dissolution, e.g., to a temperature in a range from 100° C. to 110° C.; and cooling the mixture at a rate in a range from 20° C./h to 30° C./h, whereby recrystallization of the metal-organic chalcogenide occurs to produce single-crystalline birefringent flakes having a thickness of at least 1 micron, or at least 2 microns, as described above. In some examples, the metal-organic chalcogenide may be AgSCn, where n=3-15. After cooling, the birefringent flakes may be dried to remove the solvent, and may undergo further processing, such as cleaving into smaller lateral size flakes for use.

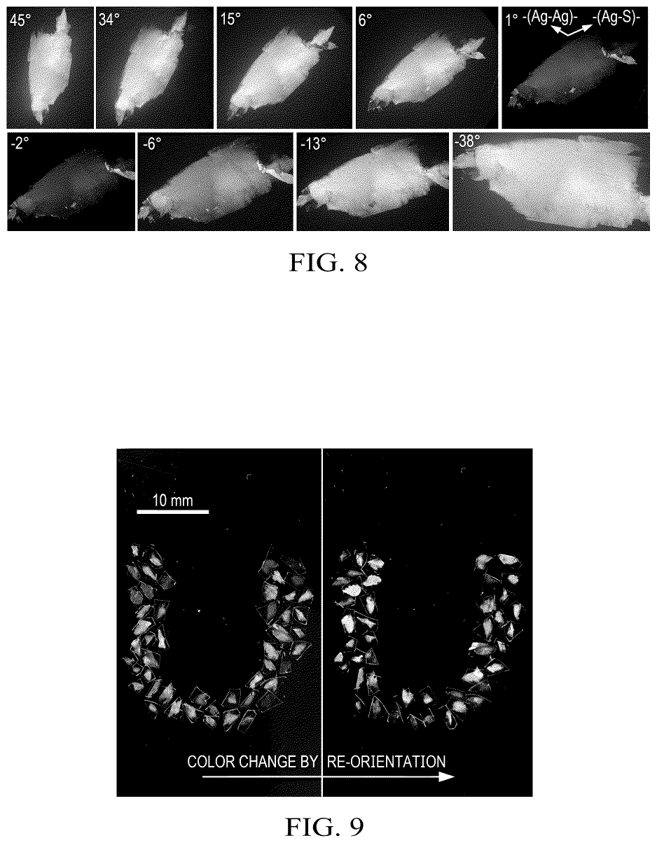

In the following, the in-plane optical anisotropy of AgSCn (n=4-8) single crystals is explored via polarization-resolved optical microscopy (PROM), with polarized illumination incident normally upon sample flakes. FIG. 1 is a schematic of the optical setup, where the optical orientations of the first linear polarizer and the second linear polarizer are positioned perpendicular to each other. A series of dark-field PROM images of a AgSC7 flake are shown in FIG. 8, as the 2D crystal gradually rotates about the [0k0] crystal axis.

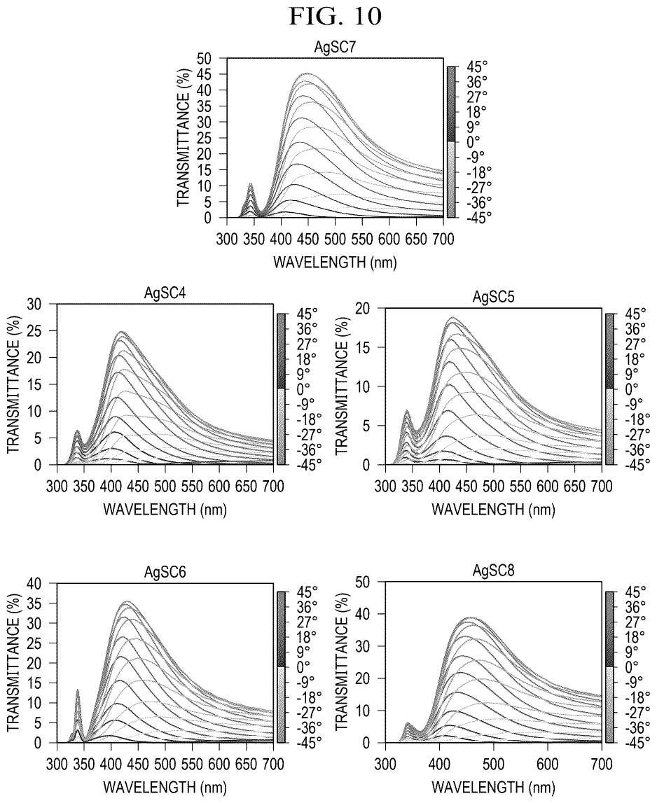

It is observed that the brightness of the flake alters progressively with a period of every 90° of sample rotation, which is typical for materials with linear dichroism or birefringence. It is also observed that the flake exhibits an asymmetric chromatic shift within the same 90° period. Assuming that 0° is roughly the rotation angle where the flake turns darkest, its color may undergo red-shift when it rotates clockwise, and blue-shift upon counter-clockwise rotation. Both shifts converge to a same chroma when the crystal appears brightest at rotation angles of about ±45°. Interestingly, if the flake is flipped such that the backside is now the frontside, the color of the flake may exhibit a blue-shift when rotated clockwise and a red-shift when rotated counter-clockwise. FIG. 9 visualizes such color alteration at the two typical hues (blue and orange). However, neither of the above observations is made if the second linear polarizer is removed, suggesting that AgSCn exhibits birefringence instead of linear dichroism.

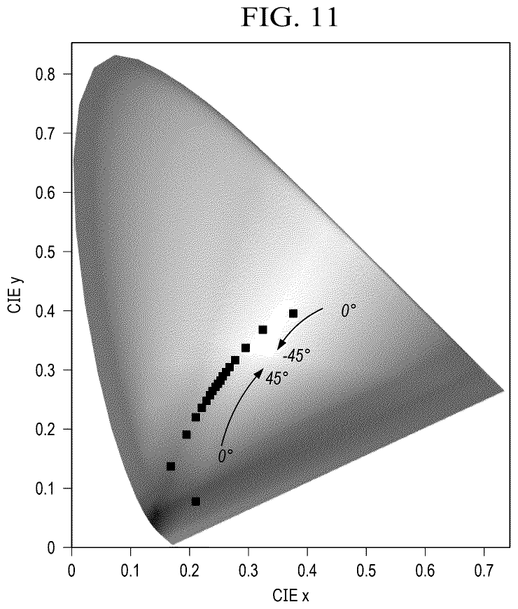

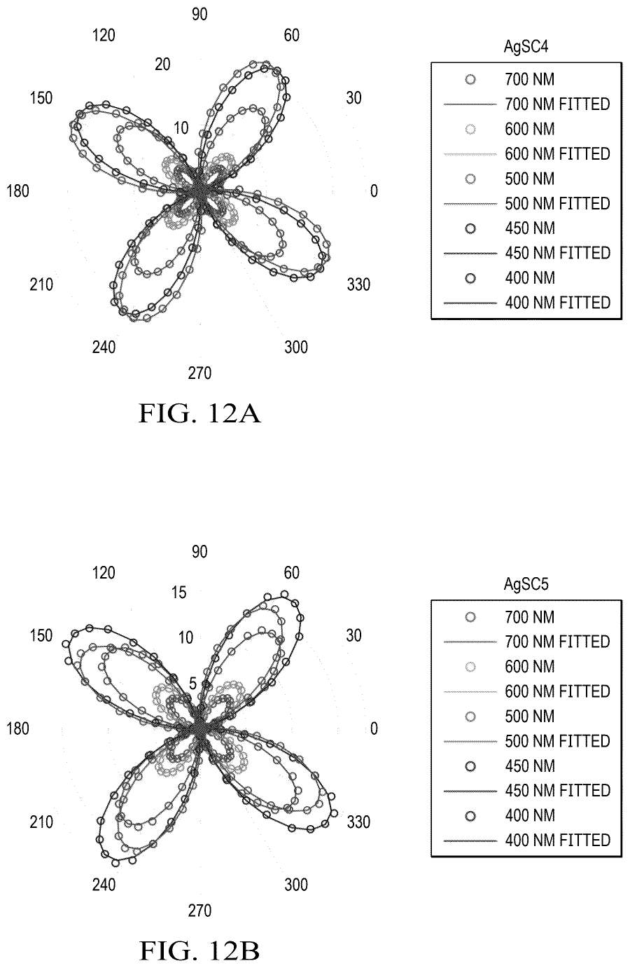

To quantify the observations, transmittance (Tr %) mode UV-vis spectroscopy is carried out using the set-up of FIG. 1 for flake rotation, where the wavelength (λ) of the incident laser ranges from 300-700 nm. All spectra are displayed in FIG. 10 for AgSCn (n=4-8), respectively. A narrow peak in the UV regime (<380 nm) and a broad peak in the visible light regime (400-700 nm) are observed for each spectrum. The overall spectrum shows a blue-shift and a red-shift upon flake rotation from 0° to 45° and 0° to −45°, respectively, along with a progressive increase of Tr %. This is consistent with the alteration of brightness/color visualized in FIG. 8. The chromaticity diagram (plotted using the CIE1931 color space) in FIG. 11 illustrates the asymmetric color shift of the AgSC7 flake upon rotation, and a wide span of chroma that covers the entire visible spectrum is identified.

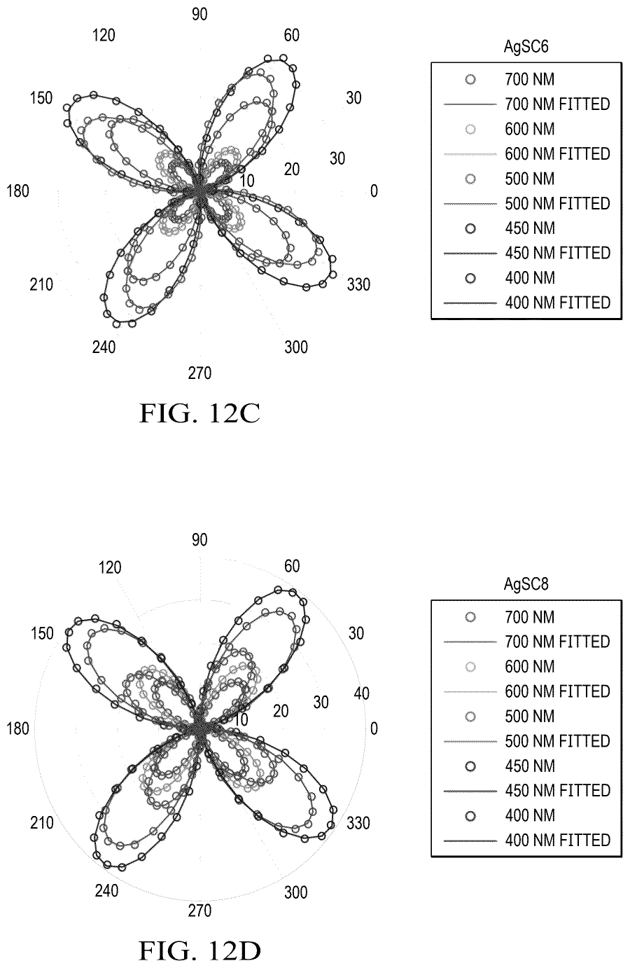

Polar plots in FIGS. 12A-12E extract the angle-resolved transmittance of incident light with λ=700, 600, 500, 450, and 400 nm. This not only confirms the 90° period of sample rotation but reveals a significant optical anisotropy from zero Tr % at 0° up to maximum Tr % of ~15-45% at around 50° for different wavelengths, respectively. In contrast, as expected, such anisotropy vanishes completely when the second linear polarizer is removed. All these observations corroborate that AgSCn is not a crystal with linear dichroism (otherwise, optical anisotropy would also show up with the first-linear-polarizer-only setup), but rather the AgSCn exhibits strong birefringence.

The seminal optical characteristics of AgSCn are promising for numerous optoelectronic and photonic applications that require optical anisotropy and color filtering, such as intelligent displays, waveplates and polarization-sensitive photodetectors, and most strikingly, such color filtering is achieved just by crystal rotation, as demonstrated in FIG. 9 where multiple AgSC7 single crystals are gathered to display the letter “U” with blue and orange color upon crystal reorientation. This inspires a novel material architecture for color filters. Such high sensitivity of crystal color upon its orientation (FIG. 8, crystal changes from blue to orange within 12° of rotation) also suggests potential applications of AgSCn as rotational motion sensors.

Fundamentally, birefringent monoclinic crystals belong to the category of biaxial material, which is featured by three principal refractive indices: nₓ, n_{y}, and n_{z}. Here, x, y, and z are axes of the dielectric frame of a crystal, which is mathematically defined as the frame where the real part of the complex dielectric permittivity tensor becomes diagonal. It should be noted that only one of the dielectric axes (i.e. y-axis) of a monoclinic system coincides with its corresponding crystal axes (i.e. b-axis, normal to the 2D flake of AgSCn in this work), while the other two orthogonal dielectric axes are off as regards to the in-plane basis (a and c axes).

By comparing the polar plots for different wavelengths incident upon AgSC7 crystal as shown in FIG. 12E, a gradual but monotonic shift of the polarization angle at maximum Tr % was identified from 45° for 2=700 nm to 54.7° for λ=400 nm. This implies an in-plane rotation of the x and z dielectric axes as the change of incident wavelength. Such dispersive dielectric frames of AgSCn are probably the reason why the color alters upon crystal rotation as observed in FIG. 8. These findings of birefringence and dispersive orientations of the dielectric frame are also observed in other AgSCn (n=4-6, 8), as shown in FIGS. 12A-12D. In order to fundamentally understand the mechanism, a phenomenological model was established that traces the rays from incident to polarizer till the convergence of the two transmitted components (ray-x and ray-z which are parallel to x and z dielectric axes, respectively) exiting the second linear polarizer, as illustrated in FIG. 13.

Two critical angles are pre-defined for the modelling: (1) θ describes the flake rotation angle defined between the in-plane optical axis of the second linear polarizer and the dielectric x-axis of the flake for incident light with λ=700 nm; (2) α(λ) is set as the orientation of the dielectric x-axis of the flake for any arbitrary A relative to that of 700 nm, and thus α (700 nm)−0°. Assuming polarized light incident to the flake is a plane wave with an electric-field amplitude of Eᵢ, the wave function of the associated ray-x and ray-z exit the second linear polarizer at a particular rotation angle (θ) for a certain λ can be written as follows:

$${E}_{x , z} ( θ , λ ) = {E}_{i} cos ( θ + α ( λ ) ) sin ( θ + α ( λ ) ) cos ( k r - ω t + \frac{2 π \cdot d \cdot {n}_{x , z}}{λ} ) \qquad ( 1 )$$

where d is the flake thickness, and Eₓ, E_{z} and nₓ, n_{z} are the electric-field amplitudes and the refractive indices of ray-x and ray-z, respectively. The measured spectra and Tr % at the second linear polarizer as the modulation of θ and λ can then be derived by combining the wave functions of the ray-x and ray-z:

$$T r ( θ , λ ) ∝ \frac{{E}^{2} ( θ , λ )}{{E}_{i}^{2}} = \frac{1}{2} {sin}^{2} ( \frac{Δ φ}{2} ) \cdot [ 1 - cos ( 4 θ + 4 α ( λ ) ) ] \qquad ( 2 )$$

where Δφ is the phase retardance between the two rays after they pass through the flake and is detailed as:

$$Δφ = \frac{2 π}{λ} Δ n \cdot d = \frac{2 π}{λ} \vert {n}_{x} - {n}_{z} \vert \cdot d \qquad ( 3 )$$

where Δn=|nₓ−n_{z}| is the metrics for the in-plane birefringence of AgSCn, which is the maximum possible difference in refractive index for incident light perpendicular to the lamellae. Full derivation of eqs. (1)-(3) is described in the modeling section below.

Eq. (2) well fits the experimental transmittance as a function of both flake rotation (θ) and incident wavelength (λ), as demonstrated in the fitted curves in FIGS. 10A-10E, with R_{sq}~0.999. Given the pre-determined flake thickness (by confocal optical microscopy), Δn and α(λ) can be estimated as fitting parameters.

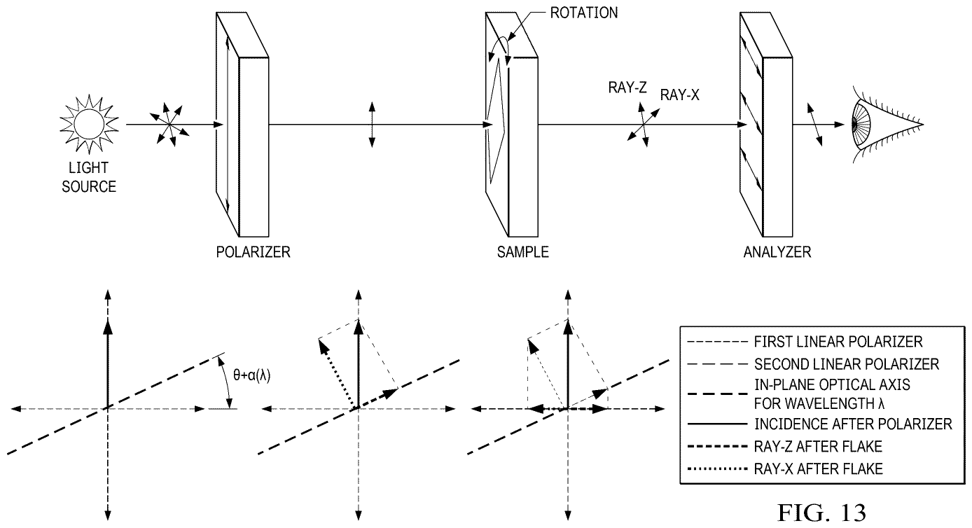

It was found that the magnitude of birefringence (Δn) of AgSCn (n=4-8), arising from the anisotropic confinement of its in-plane structure, depends highly on the wavelength of the light passing through the flake, as depicted in FIG. 14. The maximum birefringence occurs at ~427-482 nm where the magnitude varies from 0.019 to 0.03 for AgSCn of different chain lengths. Such values are an order of magnitude smaller than that of black phosphorous (Δn~0.2) and could be a limitation for devices relying on accurate manipulation of optical retardation. Also demonstrated is a potential odd/even alternation of the maximum Δn in AgSCn, as shown in the inset of FIG. 14, which, however, requires further validation with a more accurate estimation of Δn via the fitting of a series of phase retardance as the change of sample thickness.

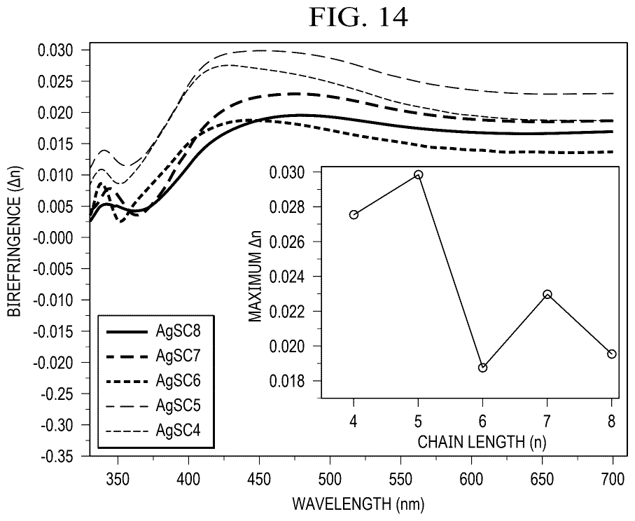

In contrast, a phenomenal rotation of the dielectric frame orientation α(λ) upon different incident wavelengths is derived for AgSCn crystals. When the crystals are positioned so that the dielectric frame orientation is 45 degrees with respect to the optical axis of the polarizers, the intensity of the corresponding light with a wavelength λ (or color) is maximized. This is the origin for the asymmetric color shift observed in FIG. 8, and thus the unique application of AgSCn as color filters. A large variation of a across wavelengths from 330-700 nm with odd/even alternations is revealed in FIG. 15 and its inset (Δα defined as α(330 nm)-α(700 nm) equals 21.6~25.7° and 17.7~19.9° for even and odd-chain AgSCn, respectively). It is believed that the origin of the dispersive orientation of the dielectric frame is closely related to the monoclinic unit cell of AgSCn and particularly, the lattice constant β. Such a phenomenon would disappear for AgSCO (hypothesized compound extrapolated from AgSCn to n=0) with high symmetry (β~90°, approximately the orthorhombic lattice) and thus Δα~0. The odd/even effect observed in lattice constants including β can also be correlated to that of Δα (which denotes the degree of dielectric frame rotation, FIG. 15 inset), where even-chain AgSCn (larger β) shows stronger dispersion than its odd-chain counterpart (smaller β), and thus exhibits larger Δα.

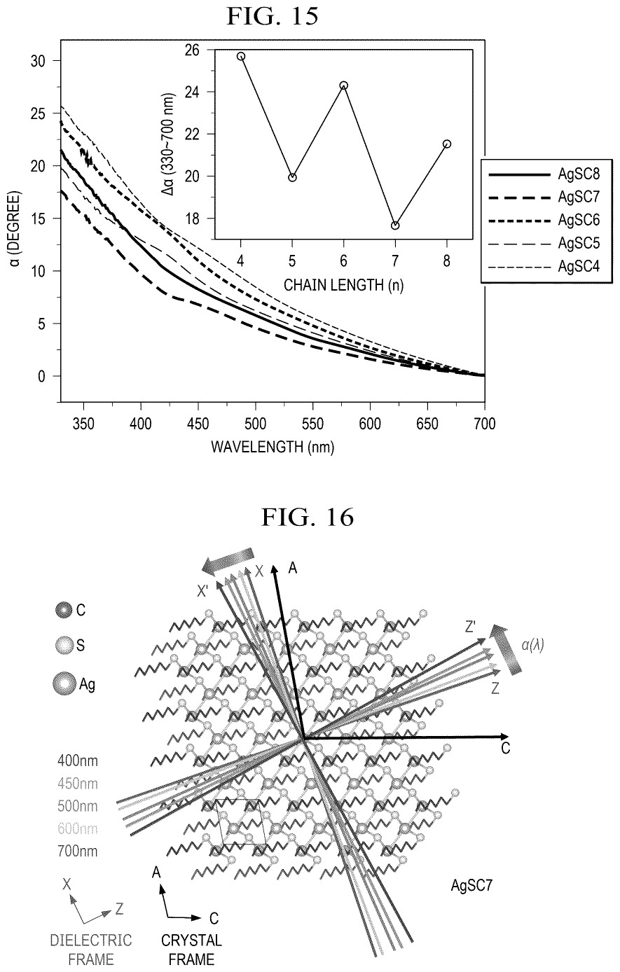

The above-mentioned in-plane anisotropy of the Ag—S network provides a showcase of the unique structure-property relationship of AgSCn. Such interplay is further explored in a more fundamental manner by analyzing the orientational correlation between the in-plane crystal axes and the derived dielectric frame. FIG. 16 overlays the potential dielectric axes of selected λ for AgSC7 on its in-plane structure. Similar to other crystals with dispersive dielectric frames, the dielectric axes of AgSCn misalign with either the —(Ag—S)_{∞}— or the —(Ag—Ag)_{∞}— crystal axis. The measurements in this study can only determine the directions of x and z in the dielectric frame but cannot distinguish between them. Hence, two sets of perpendicular dielectric axes are identified, one of which is very close to the orientation of the ligand projection.

The in-plane symmetry and anisotropy of the Ag—S network can be regulated by the evolution of alkyl ligands, which in turn undergo a systematic configurational alteration with changing chain length. This is probably a more fundamental structural reason that leads to the unique optical responses of AgSCn. The progressive tilting and rotation of alkyl chains may gradually alter their charge distribution, excitonic response, and vibrational modes, and consequently, shift the dielectric axis upon the change of incident wavelength. This hypothesis is implied by the angular dispersion of the dielectric x- or z-axis that spans from approximately along the projection of the alkyl chains for red light (FIG. 16, z-axis, red line) to that of C—S bonds for deep blue light (FIG. 16, z-axis, purple line). It is inferred that ligands play a non-negligible role in determining the non-linear optical characteristics of AgSCn. In this sense, the odd/even effect of Δn and Δα is naturally correlated with that of chain tilting/rotation and is ultimately spawned from the configurational distinction of the interlayer interfaces formed by odd or even chains, which is the origin for all sorts of “odd/even effects.”

To summarize, a substantial anisotropy in the optical and electrical characteristics of a series of 2D AgSCn (n=3-8) single crystals (of flake dimensions up to ~3 mm) with tailorable ligands has been identified. Such anisotropy fundamentally stems from the distinct in-plane characteristics of —(Ag—S)_{∞}— and —(Ag—Ag)_{∞}— orientations, along with the in-plane projection of the attached alkyl chains that undergo configurational alterations (tilting, rotation) to accommodate the lattice strain. Crystallographic measurements of the radiation-susceptible AgSCn crystals are obtained using a simple method that couples synchrotron XRD and NBD of atomic resolution and low dosage, as well as DFT relaxation that refines the position of each atom. Such a low-symmetry structure results in a mechanically-preferred cleavage orientation of the crystal, a larger electrical conductivity along the —(Ag—S)_{∞}— direction than that of —(Ag—Ag)_{∞}— direction by up to ~8 times, as well as an in-plane birefringence (of maximum Δn~0.03) with wavelength-dependent dielectric axes, which enable single crystalline AgSCn as potential building blocks for anisotropic nanodevices that require multiplex functionalities including semiconducting, birefringence and color filtering.

Another finding is the anisotropic odd/even effect that is only exhibited in the in-plane lattice along —(Ag—S)_{∞}—, rather than —(Ag—Ag)_{∞}— direction, which originates from the configurational alternation of ligand terminals. As a result, odd/even alternation is uncovered in the in-plane birefringence and the dispersive orientations of its associated dielectric frame of AgSCn. Chain parity of the out-of-plane ligands offers a new knob to modulate the in-plane optical characteristics of metal-organic chalcogenides.

### Modeling

A ray-trace phenomenological model is established based on the setup in FIG. 13 with an ideal biaxial birefringent single-crystalline flake placed in between two crossed polarizers. The light path is parallel to the b-axis of the crystal (or y-axis for dielectric frame). The x-axis of dielectric frame of AgSCn flake is θ+α(λ) with respect to the polarizing direction of the second linear polarizer, where θ is a constant and α(λ) is wavelength-dependent. It is assumed that the polarization direction (or the electrical field direction, see the blue arrow in FIG. 13) of the incident plane wave passed through the polarizer to be Eᵢ cos(kr−ωt) until it encounters the sample flake. The incident light is then split into two components after it transmits through the birefringent flake with a thickness d, one (ray-x) is parallel to the x dielectric axis and the other (ray-z) parallel to the z dielectric axis. The corresponding principal refractive indices are nₓ and n_{z}, respectively. As a result, ray-x and ray-z gain different phase shifts due to their optical path difference when transmitting through the flake, and their resulted wave function is as follows.

$$ray - z ( orange arrow ) : {E}_{i} cos ( k r - ω t + \frac{2 π d {n}_{z}}{λ} ) sin ( θ + α ( λ ) ) , \qquad ( 1 )$$

$$ray - x ( green arrow ) : {E}_{i} cos ( k r - ω t + \frac{2 π d {n}_{x}}{λ} ) cos ( θ + α ( λ ) ) . \qquad ( 2 )$$

Thus, the final light that exits the second linear polarizer is the projected-sum of the ray-x and ray-z (project along the polarization of the second linear polarizer), and can be expressed as follows with rₐ referring to the distance from sample to the second linear polarizer:

$$E ( λ , θ ) = {E}_{i} cos ( k {r}_{a} - ω t + \frac{2 π d {n}_{z}}{λ} ) sin ( θ + α ( λ ) ) cos ( θ + α ( λ ) ) - {E}_{i} cos ( k {r}_{a} - ω t + \frac{2 π d {n}_{x}}{λ} ) sin ( θ + α ( λ ) ) cos ( θ + α ( λ ) ) = {E}_{i} sin ( θ + α ( λ ) ) cos ( θ + α ( λ ) ) ( cos ( k {r}_{a} - ω t + \frac{2 π d {n}_{z}}{λ} ) - cos ( k {r}_{a} - ω t + \frac{2 π d {n}_{x}}{λ} ) = {E}_{i} sin ( 2 θ + 2 α ( λ ) ) sin ( k {r}_{a} - ω t + \frac{2 π d ( {n}_{z} + {n}_{x} )}{λ} ) sin ( \frac{π d}{λ} ( {n}_{x} - {n}_{z} ) )$$

Its intensity is proportional to the time average of [E(λ, θ)]²:

$$I ( λ , θ ) = \frac{1}{\frac{ω}{2 π}} {\int }_{0}^{\frac{2 π}{ω}} {[ E ( λ , θ ) ]}^{2} dt = \frac{ω}{2 π} {\int }_{0}^{\frac{2 π}{{ω}^{}}} {\{ {E}_{i} sin ( 2 θ + 2 α ( λ ) ) sin ( {kr}_{a} - ωt + \frac{2 π d ( {n}_{z} + {n}_{x} )}{λ} ) sin ( \frac{π d}{λ} ( {n}_{x} - {n}_{z} ) ) \}}^{2} dt = \frac{1}{4} {E}_{i}^{2} {sin}^{2} ( \frac{π d \times Δ n ( λ )}{λ} ) ( 1 - cos ( 4 θ + 4 α ( λ ) ) )$$

where Δn(λ)=|nₓ−n_{z}| is wavelength-dependent in this work. Hence, the final transmittance (Tr %) measured by the UV-vis detector is as follows:

$$T r ( λ , θ ) = \frac{I ( λ , θ )}{{I}_{i}} = \frac{I ( λ , θ )}{{E}_{i}^{2} / 2} = \frac{1}{2} {sin}^{2} ( \frac{π d \times Δ n ( λ )}{λ} ) [ 1 - cos ( 4 θ + 4 α ( λ ) ) ]$$

### Synthesis and Characterization of AgSCn Single-Crystalline Flakes

Materials: The following chemicals were purchased from Sigma-Aldrich Co. and used without further purification: silver nitrate powder (AgNO₃, ≥99.0%), acetonitrile (99.8%), triethylamine (≥99.0%) and 1-alkanethiols (1−CₙH₂ₙ₊₁SH, n=3-8, 15, ≥98%). Toluene (≥99.5%) was used as received from Macron Fine Chemicals Co.

Procedure: Multilayer AgSCn crystals with well-defined structure orderings were synthesized using a modified solution reaction method developed by the inventors.

AgSCn (n=3-8) precipitates were formed by gradually adding an AgNO₃ (1 mmol) acetonitrile (15 ml) solution into another acetonitrile (30 ml) solution of 1-alkanethiol (2 mmol) and trimethylamine (2 mmol). The mixture was stirred for 24 h in dark. The crystals were collected using vacuum filtration and washed with acetonitrile.

In order to obtain large size single crystal flakes of AgSCn (n=4-8) for detailed optical/electrical studies, a prior post-reaction recrystallization procedure was modified using passive cooling with better temperature controllability. Details are as follows:

20-60 mg (e.g., 50 mg) AgSCn (n=4-8) precipitates and 20 ml hot toluene are mixed in a sealed container and the solution was heated until complete dissolution on the thermal plate. Then the thermal plate undergoes controlled cooling process (cooling rate in a range from 20-30° C./h) in order to promote slow recrystallization of AgSCn in toluene.

Polarization-resolved optical microscope: Polarization-resolved optical images of AgSCn flake at different flake rotation angles were taken via Zeiss Axiovert Inverted Optical Microscope in transmitted illumination mode (halogen light source).

Polarization-resolved UV-vis spectroscopy: Polarization-resolved UV-vis spectroscopy was conducted via Varian Cary 5G spectrophotometer in the transmission mode (wavelength ranges from 250 to 700 nm). A large AgSCn flake was transferred onto a quartz wafer and is positioned between two crossed polarizing films (first linear polarizer and second linear polarizer) on the light path of the spectrophotometer, per FIG. 1. Transmittance data of each sample were collected with sample rotation from −45° to 45° at a step size of 5°. A sample-free baseline was collected at every rotation angle in advance of each test.

Confocal optical microscope: The morphology of AgSCn flakes including lateral dimensions, flake thicknesses and 3D landscapes were obtained by a Keyence VK-X1000 3D Laser Scanning Confocal Microscope with a 404 nm laser source.

This disclosure also includes the following aspects:

A first aspect relates to a method of producing color for a display, the method comprising: emitting light from a light source in optical communication with an optical system comprising: a first linear polarizer; a second linear polarizer cross-polarized with respect to the first linear polarizer; and a birefringent flake comprising a metal-organic chalcogenide positioned between the first and second linear polarizers, the birefringent flake being oriented along a plane parallel to the first and second linear polarizers; and rotating the birefringent flake within the plane, wherein a color of the light transmitted through the optical system changes as the birefringent flake is rotated.

A second aspect relates to the method of the first aspect, wherein the metal-organic chalcogenide comprises: a metal selected from the group consisting of Ag, Au and Cu; a chalcogen selected from the group consisting of S, Se and Te; and organic ligands comprising alkyl chains (CₙH₂ₙ₊₁), wherein n represents carbon chain length.

A third aspect relates to the method of the second aspect, wherein the metal-organic chalcogenide comprises silver alkanethiolate (AgSCₙH₂ₙ₊₁ or AgSCn).

A fourth aspect relates to the method of the second or the third aspect, wherein the carbon chain length n is in a range from 3 to 15, or from 3 to 8.

A fifth aspect relates to the method of any of the second through the fourth aspects, wherein an amount of rotation required to obtain a given color depends on the carbon chain length.

A sixth aspect relates to the method of any of the first through the fifth aspects, wherein the birefringent flake has a thickness of at least 1 micron.

A seventh aspect relates to the method of the sixth aspect, wherein an intensity of the light transmitted through the optical system depends on the thickness of the birefringent flake.

An eighth aspect relates to the method of any of the first through the seventh aspects, wherein the birefringent flake is single-crystalline.

A ninth aspect relates to the method of any of the first through the eighth aspects, wherein the birefringent flake has a monoclinic crystal structure, and wherein the rotation of the birefringent flake occurs about a b-axis of the monoclinic crystal structure.

A tenth aspect relates to the method of any of the first through the ninth aspects, wherein the rotation of the birefringent flake occurs about an axis perpendicular to the first and second linear polarizers.

An eleventh aspect relates to the method of any of the first through the tenth aspects, wherein rotating the birefringent flake in a clockwise direction leads to a red shift or a blue shift in the color.

A twelfth aspect relates to the method of any of the first through the eleventh aspects, wherein the light source is a white light source.

A thirteenth aspect relates to the method of any of the first through the twelfth aspects, wherein the color has a wavelength in a range from about 400 nm to about 700 nm.

A fourteenth aspect relates to the method of any of the first through the thirteenth aspects, wherein the birefringent flake is supported on an optically transparent, non-polarizing substrate.

A fifteenth aspect relates to the method of any of the first through the fourteenth aspects, wherein the rotation is driven by a motor electrically connected to a controller.

A sixteenth aspect relates to a pixel for a display, the pixel comprising: an optical system including: a first linear polarizer; a second linear polarizer cross-polarized with respect to the first linear polarizer; and a birefringent flake comprising a metal-organic chalcogenide positioned between the first and second linear polarizer, the birefringent flake being oriented along a plane parallel to the first and second linear polarizers, wherein the birefringent flake is rotatable within the plane, and wherein, when light from a light source passes through the optical system, the light transmitted has a color depending on a rotation angle of the birefringent flake.

A seventeenth aspect relates to the pixel of the sixteenth aspect, wherein the optical system further comprises an optically transparent, non-polarizing substrate supporting the birefringent flake.

An eighteenth aspect relates to the pixel of the seventeenth aspect, wherein the optically transparent, non-polarizing substrate comprises glass.

A nineteenth aspect relates to the pixel of any of the sixteenth through the eighteenth aspects, wherein the optically transparent, non-polarizing substrate is configured to undergo manual or automatic rotation to rotate the birefringent flake within the plane.

A twentieth aspect relates to the pixel of any of the sixteenth through the nineteenth aspects, further comprising a motor operably connected to the optically transparent, non-polarizing substrate to control the rotation of the birefringent flake.

A twenty-first aspect relates to the pixel of any of the sixteenth through the twentieth aspects, wherein the metal-organic chalcogenide comprises: a metal selected from the group consisting of Ag, Au and Cu; a chalcogen selected from the group consisting of S, Se and Te; and organic ligands comprising alkyl chains (CₙH₂ₙ₊₁), wherein n represents carbon chain length.

A twenty-second aspect relates to the pixel of the twenty-first aspect, wherein the metal-organic chalcogenide comprises silver alkanethiolate (AgSCₙH₂ₙ₊₁ or AgSCn).

A twenty-third aspect relates to the pixel of the twenty-first or the twenty-second aspect, wherein the carbon chain length n is in a range from 3 to 15, or from 3 to 8.

A twenty-fourth aspect relates to the pixel of any of the sixteenth through the twenty-third aspects, wherein the birefringent flake has a thickness of at least 1 micron.

A twenty-fifth aspect relates to the pixel of any of the sixteenth through the twenty-fourth aspects, wherein the birefringent flake is single-crystalline.

A twenty-sixth aspect relates to the pixel of any of the sixteenth through the twenty-fifth aspects, wherein the birefringent flake has a monoclinic crystal structure, and wherein a b-axis of the monoclinic crystal structure is normal to the first and second linear polarizers.

A twenty-seventh aspect relates to the pixel of any of the seventeenth through the twenty-sixth aspects, further comprising a cylindrical framework that contains the optical system, wherein the optically transparent, non-polarizing substrate has a circular shape and is rotatable within the cylindrical framework.

A twenty-eighth aspect relates to the pixel of the twenty-seventh aspect, further comprising a motor operably connected to a rotatable portion of the cylindrical framework, wherein the optically transparent substrate is configured to rotate along with the rotatable portion of the cylindrical framework.

A twenty-ninth aspect relates to a display comprising an array of the pixels of any of the sixteenth through the twenty-eighth aspects.

A thirtieth aspect relates to a method of making birefringent flakes for optical applications, the method comprising: dissolving a metal-organic chalcogenide in a solvent to form a mixture, wherein the metal-organic chalcogenide has a concentration in a range from 6 μmol/ml to 15 μmol/ml in the mixture; heating the mixture to ensure complete dissolution of the metal-organic chalcogenide; cooling the mixture at a rate in a range from 20° C./h to 30° C./h, whereby recrystallization of the metal-organic chalcogenide occurs; and obtaining single-crystalline birefringent flakes comprising the metal-organic chalcogenide and having a thickness of at least about 1 micron.

A thirty-first aspect relates to the method of the thirtieth aspect, wherein the metal-organic chalcogenide comprises: a metal selected from the group consisting of Ag, Au and Cu; a chalcogen selected from the group consisting of S, Se and Te; and organic ligands comprising alkyl chains (CₙH₂ₙ₊₁), wherein n represents carbon chain length.

A thirty-second aspect relates to the method of the thirtieth or the thirty-first aspect, wherein the metal-organic chalcogenide comprises silver alkanethiolate (AgSCₙH₂ₙ₊₁ or AgSCn).

A thirty-third aspect relates to the method of any of the thirtieth through the thirty-second aspects, wherein the carbon chain length n is in a range from 3 to 15, or from 3 to 8.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

While various embodiments have been described, it will be apparent to those of ordinary skill in the art that many more embodiments and implementations are possible. Accordingly, the embodiments described herein are examples, not the only possible embodiments and implementations.

What is claimed is:

1. A method of producing color for a display, the method comprising:
emitting light from a light source in optical communication with an optical system comprising: a first linear polarizer; a second linear polarizer cross-polarized with respect to the first linear polarizer; and a birefringent flake comprising a metal-organic chalcogenide positioned between the first and second linear polarizers, the birefringent flake being oriented along a plane parallel to the first and second linear polarizers; and
rotating the birefringent flake within the plane,
wherein a color of the light transmitted through the optical system changes as the birefringent flake is rotated.

2. The method of claim 1, wherein the metal-organic chalcogenide comprises: a metal selected from the group consisting of Ag, Au and Cu; a chalcogen selected from the group consisting of S, Se and Te; and organic ligands comprising alkyl chains (CₙH₂ₙ₊₁), wherein n represents carbon chain length.

3. The method of claim 2, wherein the metal-organic chalcogenide comprises silver alkanethiolate (AgSCₙH₂ₙ₊₁ or AgSCn).

4. The method of claim 2, wherein the carbon chain length n is in a range from 3 to 15.

5. The method of claim 2, wherein an amount of rotation required to obtain a given color depends on the carbon chain length.

6. The method of claim 1, wherein the birefringent flake has a thickness of at least 1 micron.

7. The method of claim 6, wherein an intensity of the light transmitted through the optical system depends on the thickness of the birefringent flake.

8. The method of claim 1, wherein the birefringent flake is single-crystalline.

9. The method of claim 1, wherein the birefringent flake has a monoclinic crystal structure, and
wherein the rotation of the birefringent flake occurs about a b-axis of the monoclinic crystal structure.

10. The method of claim 1, wherein the rotation of the birefringent flake occurs about an axis perpendicular to the first and second linear polarizers.

11. The method of claim 1, wherein the color has a wavelength in a range from about 400 nm to about 700 nm.

12. A pixel for a display, the pixel comprising:
an optical system including:
a first linear polarizer;
a second linear polarizer cross-polarized with respect to the first linear polarizer; and
a birefringent flake comprising a metal-organic chalcogenide positioned between the first and second linear polarizer, the birefringent flake being oriented along a plane parallel to the first and second linear polarizers,
wherein the birefringent flake is rotatable within the plane, and
wherein, when light from a light source passes through the optical system, the light transmitted has a color depending on a rotation angle of the birefringent flake.

13. The pixel of claim 12, wherein the optical system further comprises an optically transparent, non-polarizing substrate supporting the birefringent flake.

14. The pixel of claim 13, wherein the optically transparent, non-polarizing substrate is configured to undergo manual or automatic rotation to rotate the birefringent flake within the plane.

15. The pixel of claim 12, wherein the metal-organic chalcogenide comprises: a metal selected from the group consisting of Ag, Au and Cu; a chalcogen selected from the group consisting of S, Se and Te; and organic ligands comprising alkyl chains (CₙH₂ₙ₊₁), wherein n represents carbon chain length.

16. The pixel of claim 15, wherein the metal-organic chalcogenide comprises silver alkanethiolate (AgSCₙH₂ₙ₊₁ or AgSCn).

17. The pixel of claim 12, further comprising a cylindrical framework that contains the optical system,
wherein the optically transparent, non-polarizing substrate has a circular shape and is rotatable within the cylindrical framework.

18. The pixel of claim 17, further comprising a motor operably connected to a rotatable portion of the cylindrical framework,
wherein the optically transparent substrate is configured to rotate along with the rotatable portion of the cylindrical framework.

19. A display comprising an array of the pixels of claim 12.

20. A method of making birefringent flakes for optical applications, the method comprising:
dissolving a metal-organic chalcogenide in a solvent to form a mixture, wherein the metal-organic chalcogenide has a concentration in a range from 6 μmol/ml to 15 μmol/ml in the mixture;
heating the mixture to ensure complete dissolution of the metal-organic chalcogenide;
cooling the mixture at a rate in a range from 20° C./h to 30° C./h, whereby recrystallization of the metal-organic chalcogenide occurs; and
obtaining single-crystalline birefringent flakes comprising the metal-organic chalcogenide and having a thickness of at least about 1 micron.
